(19) United States
(12) Patent Application Publication
(10) Pub. No.: US 2009/0014746 A1
(43) Pub. Date: Jan. 15, 2009

(54) SOLDER ALLOYS

(76) Inventors: Ainissa Gweneth Ramirez, New Haven, CT (US); Roger Sinta, Woburn, MA (US)

Correspondence Address: JOHN F. BOHLAND, P. O. BOX 70, NEW BERN, NC, 28563, US

(21) Appl. No.: 11/776,378

(22) Filed: Jul. 11, 2007

(51) Int. Cl. C22C 13/00; C22C 28/00; C22C 5/02; C22C 5/06; H01L 33/00

(52) U.S. Cl. 257/99; 420/501; 420/502; 420/507; 420/555; 420/557; 420/560; 438/116; 257/E33.001

(57) ABSTRACT

Lead-free solder compositions for bonding and sealing flat panel displays, CCD's, solar cells, light emitting diodes, and other optoelectronic devices are disclosed. The solders are based on alloys of Sn, Au, Ag, and Cu and one or more rare earth metals chosen from the following, Y, La, Ce, Pr, Sc, Sm, Gd, Tb, Dy, Ho, Er, Tm, Yb, and Lu. Optionally, the compositions may comprise In, Bi, or Zn. The solder compositions exhibit superior bonding capability in joining dissimilar surfaces such as those present in both the flat panel display and light emitting devices. Additionally the solders provide a strong barrier to the diffusion of both water and oxygen into these devices thus promoting longer device life times.

This application is a continuation-in-part of pending application Ser. No. 11/424,412, which is incorporated herein by reference. The present invention relates to oxide-bondable solder alloys, methods for using the alloys, and articles comprising the alloys.

### BACKGROUND OF THE INVENTION

A variety of substrates are used in the fabrication of optical and optoelectronic devices and these substrates are often coated with a second or third material sometimes in a patterned fashion. In most cases the fabrication process requires that the substrate either be bonded to, or encapsulated by, a second material or used as a seal for a hermetically sealed container that is typically composed of a dissimilar material. Substrates and surface materials can include glasses, ceramics, polymers, metals, and metal oxides. Further, in some cases the substrates not only need to be mechanically engaged with each other, the material used to bind the surfaces must also act as a light shield or as a barrier to gases such as water vapor and oxygen. Finally, in other scenarios the sealant may also act as a conductive pathway for the device.

Solder is employed in a variety of components including photonic devices, optical fiber assemblies, semiconductor devices, and a number of types of flat panel displays. Typically in many of these devices multilayer films are employed such as indium tin oxide (ITO), which has good adhesion to substrates such as silicon oxide, glasses and ceramics. Such materials usually do not bond well with standard solders for providing good electrical connections or the prevention of contamination. As a result films like ITO must be first covered with a solderable outer layer such as gold or platinum so that effective adhesion between the device and the substrate is achieved.

Although copper and gold films are wettable to solder, these have poor adhesion to glass substrates. Silver film has reasonable adhesion and excellent solder wetting properties but suffers from electromigration. Aluminum and chromium films also adhere well to glass substrates but are not wettable to standard tin-lead solders. Thus, in the past, multi-layered metal coatings have been employed with a first layer having excellent adhesion properties deposited onto a substrate followed by one or more over layers of material with the last layer having excellent wettability to solder to improve interfacial adhesion. Depositing such multiple film layers may require heating at temperatures of greater than 350° C. to assure adhesion. When, however, heating a substrate during such thin film coating, some devices can be destroyed or the properties adversely affected. Another difficulty with some multilayer thin films results from the fact that internal strains can be introduced into the stack. Further, the increased number of process steps results in increased costs and potentially decreased yields.

Increased adhesion to substrates may be achieved by first cleaning or modifying the surfaces via chemical or physical methods. Flux is typically used for metal surfaces to remove impurities, and in other cases, a process such as plasma treatment of surfaces or sputtering is used. Both of these treatments may increase the contamination of the device which will reduce reliability, and both increase the cost of the device.

Recently, and in the past, materials known as solder glasses have been used for sealing and bonding photonic devices. Typically these compositions comprise silicon oxide mixed with various other metal oxides and are used for sealing and attaching component assemblies such as lead wires to electric lighting devices such as standard lamps and flat fluorescent lamps used in flat panel displays as back lights. Solder glasses exhibit excellent bonding to metal and metal oxide surfaces. However these must be processed at temperatures near or above 600° C. and as such are not suitable for use in advanced lighting sources based on organic electroluminescent devices since exposure to these extreme temperatures would damage the emission layer, increase contamination, and reduce the reliability of the devices. Using a metal-based solder material that exhibits enhanced adhesion and the ability to tune the application temperature would be superior.

Polymer-based adhesives have also been used to seal photonic devices such as flat panel displays and other photonic elements. These demonstrate good adhesion to dissimilar substrates and can be used at low application temperatures. These materials can however leak light, interact unfavorably with the optically active elements of the device (e.g. the liquid crystal), and do not prevent the diffusion of either water vapor or oxygen into the device. Modifications to the polymer-based adhesives can be made to assuage the first two cases (e.g. filling with carbon black to prevent light leakage). However the latter case is critical for the long-term reliability of organic electroluminescent-based displays (OLED, POLED, PHOLED), solar cells, and LEDs (organic and inorganic-based). This property is more difficult to improve. In all of the aforementioned cases a solder capable of bonding to the surfaces of interest that acts as a more effective barrier as well as a sealant is preferred.

Rare earth metal-containing solders have been known for some time and have been utilized for bonding surfaces which are not wet well and subsequently not bonded effectively by standard solder compositions (e.g. eutectic Sn/Pb and the more recent lead free solders based on Sn/Ag). More recently a series of solder compositions were disclosed by scientists at Bell Laboratories (Applied Physics Letters, Vol. 17(19), 2976, 2001) that proved to be highly effective for bonding oxide surfaces and other difficult to bond materials such as TiN, diamond and ZnSe. These compositions wet both oxide and metal surfaces very well and form strong bonds with these. In addition these materials eliminate both the need to clean metal surfaces by chemical or physical means and the requirement to perform multilevel metallizations on substrates like glass in order to get the solder to adhere well.

U.S. Pat. Nos. 6,231,693; 6,306,516; 6,319,617; and 6,367,683, which are incorporated herein by reference, disclose solder compositions containing rare earth elements.

Glasses and oxide-based substrates are generally used in optical and optoelectronic devices. In many cases these act as windows for either the emission or absorption of light. Further these devices require that a “window” be attached to a substrate that can be comprised of materials such as Si, SiO₂, various ceramics, or III-V semiconductors.

### SUMMARY OF THE INVENTION

The present invention relates to particular lead-free solder compositions for bonding and sealing flat panel displays, CCD's, solar cells, light emitting diodes, and other optoelectronic devices. The solders are based on alloys of Sn, Au, Ag, and Cu and one or more rare earth metals chosen from the following, Y, La, Ce, Pr, Sc, Sm, Gd, Tb, Dy, Ho, Er, Tm, Yb, and Lu. Optionally, the compositions may comprise In, Bi, or Zn. The solder compositions exhibit superior bonding capability in joining, mounting, sealing, and encapsulating dissimilar materials such as those present in both the flat panel display and light emitting devices. Additionally the solders provide a strong barrier to the diffusion of both water and oxygen into these devices thus promoting longer device life times.

It is an object of the present invention to provide solder compositions having good bonding adhesion to the substrates used in optoelectronic devices such as displays, solar cells and light emitting devices

It is also an object of the present invention to provide solder compositions having application temperature ranges matching the requirements imposed by the thermal characteristics of optoelectronic devices.

It is a further object of the present invention to provide solder compositions that serve as barriers to moisture and oxygen in optoelectronic devices.

It is also an object of the present invention to provide methods for packaging optoelectronic devices using solder compositions according to the present invention.

It is a further object of the present invention to provide optoelectronic devices comprising solder compositions according to the present invention.

### BRIEF DESCRIPTION OF THE DRAWINGS

FIG. 1 shows a generic structure of an optoelectronic device comprising a solder composition according to the present invention.

FIG. 2 is a detailed view of an array of optical devices encapsulated unto a larger package according to the present invention.

FIG. 3 is an organic light emitting diode display (OLED) unit comprising a solder composition according to the present invention.

FIG. 4 is a display device comprising a solder composition according to the present invention and containing spacer elements.

FIG. 5 is another embodiment of the present invention in an OLED display.

FIG. 6. shows the use of solders according to the present invention in packaging inorganic LEDs.

### DETAILED DESCRIPTION OF PREFERRED EMBODIMENTS

Preferred compositions according to the present invention include compositions containing 70-99 wt % tin (Sn), 0.1-30 wt % silver (Ag) or gold (Au), 0.1-5 wt % copper (Cu), and 0.01-5 wt % rare earth metal selected from yttrium (Y), lanthanum (La), cerium (Ce), praseodymium (Pr), scandium (Sc), samarium (Sm), gadolinium (Gd), terbium (Tb), dysprosium (Dy), holmium (Ho), erbium (Er), thulium (Tm), ytterbium (Yb), and lutetium (Lu). In particularly preferred compositions, the rare earth metal is either erbium (Er), lutetium (Lu), or cerium (Ce).

Additional preferred compositions according to the present invention include compositions containing 30-98 wt % indium (In), 0.5-10 wt % silver (Ag), and 0.01-5 wt % rare earth metal selected from yttrium (Y), lanthanum (La), cerium (Ce), praseodymium (Pr), scandium (Sc), samarium (Sm), gadolinium (Gd), terbium (Tb), dysprosium (Dy), holmium (Ho), erbium (Er), thulium (Tm), ytterbium (Yb), and lutetium (Lu).

More preferred compositions according to the present invention include compositions containing 30-70 wt % indium (In), 20-60 wt % tin (Sn), and 0.01-5 wt % rare earth metal selected from yttrium (Y), lanthanum (La), cerium (Ce), praseodymium (Pr), scandium (Sc), samarium (Sm), gadolinium (Gd), terbium (Tb), dysprosium (Dy), holmium (Ho), erbium (Er), thulium (Tm), ytterbium (Yb), and lutetium (Lu).

The solder compositions described herein can be used in a variety of forms. In one form, solder powders can be employed in conjunction with a suitable binder to form a paste or cream. Typically, a ratio of 85-90% solder to 10-15% binder is used. These can be applied via syringes, automated dispensers (i.e. spraying or ink jetting), or by screen printing. When using the solder in paste form the binder must first be burned off before joining the surfaces. Alternatively the powder can be placed in the device in the dry form and heated to form the bond.

Pellets or ingots can also be used. These are either used with hand soldering or pre-melted and then spread by mechanical means to form thin layers. Metal solder brushes and doctor blades are typically used. Pre-formed solder balls of uniform dimensions can also be used. These are especially useful to attach chips to other substrates. Ovens, hot plates, soldering irons, ultrasonic irons, probes and baths, spot welding, reactive bonding, and laser induced heating can be used to melt the solder and pre-heat the surfaces to be joined.

Solders according to the present invention can also be formed into wires (by extrusion), sheets or foils (by rolling), or as pre-forms (cut precisely from sheets). Generally the pre-forms are cut to the shape and dimensions of the parts to be joined. Typically all of these are formed in thin dimensions and the melting methods are the same as the aforementioned techniques.

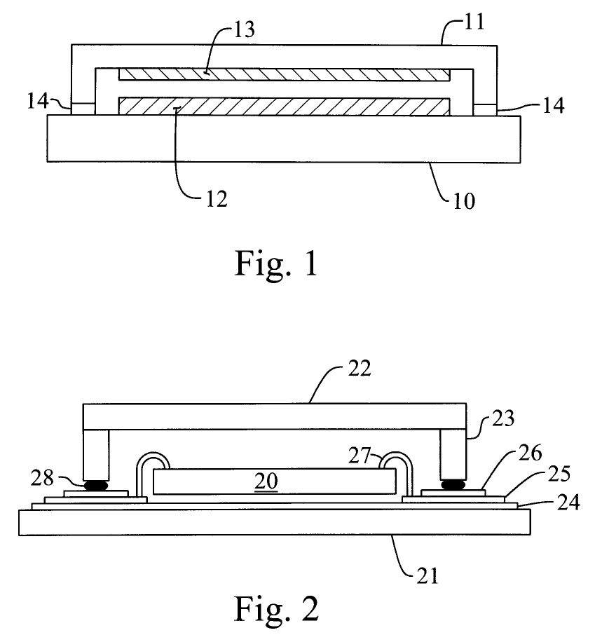

FIG. 1 shows generically an optoelectronic device comprising a solder formulation according to the present invention. This structure is a modification of the structure described in U.S. Pat. Appl. No. 2005/0277355, which is incorporated herein by reference. In this case, the layers marked 12 and 13 represent the active (i.e. light emitting or absorbing) elements, 11 is a transparent window, and 10 a substrate. The sealant, 14, is a solder composition according to the present invention.

FIG. 2 shows in more detail a device comprising a solder composition according to the present invention. This structure is a modification of that shown in FIG. 8 of International Publication Number WO 2004/091838, which is incorporated herein by reference. An array of optical devices 20 is encapsulated into a larger package comprising a silicon substrate 21, a transparent window 22, a spacer 23, a first SiO₂ layer 24, an electrical wiring layer 25, a second SiO₂ layer 26, and wire bonds 27. The solder 28 is used both to seal the active element of the device from the atmosphere and also to bond the transparent window to the spacers. In the device according to the present invention, the solder 28 is a composition according to the present invention. Conventional solders cannot be used in this application because they do not effectively adhere to materials such as glass or quartz. Prior art solder compositions containing rare earth elements frequently require an oxygen-free atmosphere in order to form adequate bonds to these surfaces. The process of forming the above device comprises the following steps;

1) Defining the electrical wiring on the Si substrate

2) Attaching the MEMs device array to the substrate and wiring bonding it

3) locating the solder seal

4) attaching the spacers

5) attaching the transparent window

These solder compositions can be used to both attach to the substrate and seal an individual device and to form the final device package.

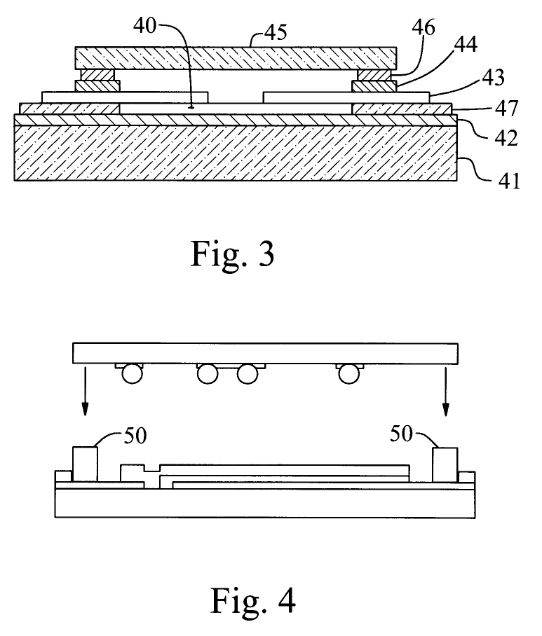

FIG. 3 shows an embodiment of the present invention in which a packaged organic light emitting diode (OLED) display element comprises a solder composition according to the present invention. It is a modification of the structure shown in FIG. 14B of U.S. Pat. No. 5,703,436, which is incorporated herein by reference. The active device area is OLED stack 40. Glass substrate 41 is coated with a thin (not to scale) layer of ITO, 42. Contact layer 43 is between SiO₂ layers 47 and 44, and this layer is bonded to cover glass 45 with solder 46. In this case, a solder pre-form having a composition in accordance with the present invention is used and will bond directly to the glass surfaces. In contrast, the device described in U.S. Pat. No. 5,703,436 used an intermediate metal ring on the glass to enable solder adhesion between the SiO₂ layer and the cover glass. The metal ring can be eliminated with the use of solders according to the present invention due to their ability to adhere directly to glass surfaces. Elimination of the metal layer allows the solder to be heated directly by a laser through the cover glass.

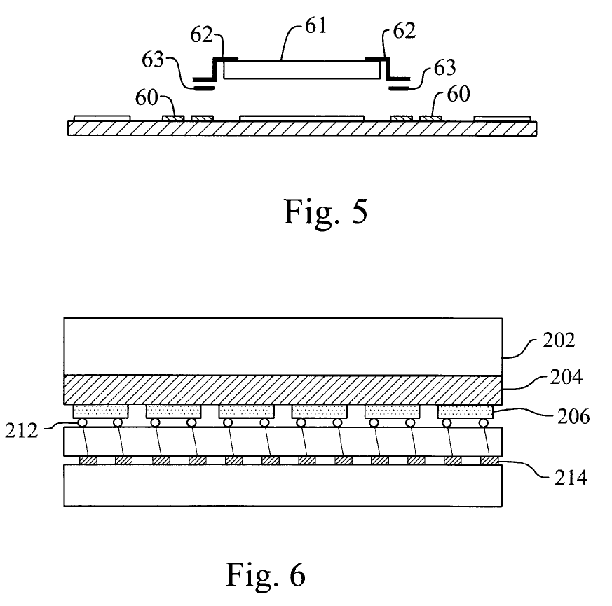

The solder compositions according to the present invention can also be used in display devices that contain spacer elements that are pre-attached or added to the active area as shown in FIG. 4. The device shown is, except for the solder composition, similar to the device shown in FIG. 5 of U.S. Pat. No. 6,952,078, which is incorporated herein by reference. Here the top element with the spacers (balls) attached is brought into contact with the active element-containing substrate and sealed via a sealing ring 50 which again is comprised of solder according to the present invention that can easily bond to the transparent window and the substrate (Si, SiO₂, III-V semiconductor etc.). In this case the substrate can be made of plastic and in such cases low melting solder compositions can be employed.

Another construction of such an OLED device is shown in FIG. 5. This is a modification of the device shown in FIG. 2 of U.S. Pat. No. 6,608,283, which is incorporated herein by reference. Here a sealing band 60 is preformed on the substrate and joined to the cover glass 61 that is outfitted with a flange 62 that has a solder preform 63 on it. The sealing band and the reflow of the solder provide the gap control and a barrier to oxygen and moisture for this OLED device. The sealing band can be fabricated from the present solder or eliminated since these solders are capable of bonding effectively to the substrate.

In FIG. 6, a basic outline of an inorganic based LED is shown. The structure shown in FIG. 2(b) of U.S. Pat. Appl. No. 2005/0287833, which is incorporated herein by reference, is modified by using solder compositions according to the present invention. The substrate 202 is sapphire in this case and shown on top. Epitaxial layer 204 is grown on the LED die 206. Both of these can be made of a variety of materials depending on the power and color output of the LED. Typically these are III-V semiconductors and metal oxides. In this structure solder according to the present invention is used to edge bond the sapphire substrate. Again, normal solders do not wet this material.

The LED die is attached to another substrate, in this case a PW board via conductive bumps 212 which can be made from the present solder as it has sufficient conductivity to make the electrical connection. The entire device package is then attached to the PWB via solder joints 214. In this case the solder can be used in multiple steps and performs several functions.

### EXAMPLES

In each of the examples below a known quantity of solder ingot was placed upon a copper substrate that was first wetted with flux (Nihon Genma MF-255GQ) and heated to 270° C. After the solder was fully melted, it was allowed to spread for 120 seconds after which the substrate was cooled. The area of the solder spreading was measured by conventional techniques.

### Example 1

### Sn/Ag/Cu/Er (95.25/3.8/0.7/0.25 wt-%)

Good wetting of the substrate was observed and the measured area of spreading was 19.44 mm².

### Example 2

### Sn/Ag/Cu/Er (95/3.8/0.7/0.5 wt-%)

Good wetting of the substrate was observed and the measured area of spreading was 19.63 mm².

### Example 3

### Sn/Ag/Cu/Er (95/3.5/0.5/1.0 wt-%)

Good wetting of the substrate was observed and the measured area of spreading was 23.76 mm².

### Example 4

### Sn/Ag/Cu/Lu (96.3/3.0/0.45/0.25 wt-%)

Good wetting of the substrate was observed and the measured area of spreading was 19.35 mm².

### Example 5

### Sn/Ag/Cu/Lu (96.1/3.1/0.4/0.4 wt-%)

Good wetting of the substrate was observed and the measured area of spreading was 19.50 mm².

In the next set of examples a small, known quantity of solder was placed on a pre-heated (270° C.) glass slide (pre-cleaned with isopropanol) and allowed to melt. A second glass slide was placed on top and a small amount of shear was applied. The assembly was then cooled and tested for adhesion.

### Example 6

### Sn/Ag/Cu/Er (95.25/3.8/0.7/0.25 wt-%)

Good adhesion was observed. The assembly could not be pulled apart.

### Example 7

### Sn/Ag/Cu/Er (95/3.8/0.7/0.5 wt-%)

Good adhesion was observed. The assembly could not be pulled apart.

### Example 8

### Sn/Ag/Cu/Er (95/3.5/0.5/1.0 wt-%)

Good adhesion was observed. The assembly could not be pulled apart.

### Example 9

### Sn/Ag/Cu/Lu (96.3/3.0/0.45/0.25 wt-%)

Good adhesion was observed. The assembly could not be pulled apart.

### Example 10

### Sn/Ag/Cu/Lu (96.1/3.1/0.4/0.4 wt-%)

Good adhesion was observed. The sample assembly could not be pulled apart.

### COMPARATIVE EXAMPLES

Conventional solder alloys were used for the following comparative examples.

### Comparative Example 1

A sample of standard Sn/Ag/Cu (96/3.5/0.5 wt-%) was subjected to the conditions of the spread test as described (vide supra). Some wetting of the substrate was observed and the measured area of spreading was 15.71 mm².

### Comparative Example 2

A sample of standard Sn/Ag/Cu (96/3.5/0.5 wt-%) was subjected to the conditions of the glass bonding as described (vide supra). In this case no adhesion was observed and the sample was easily pulled apart yielding two clean glass substrates and a film of solder.

What is claimed is:

1. A solder alloy comprising:
a. 0.1-99% by weight of tin,
b. 0.1-5% by weight of copper,
c. 0.1-90% by weight of an element selected from the group consisting of silver and gold,
d. 0.1-5% by weight of an element selected from the group consisting of yttrium, lanthanum, cerium, praseodymium, scandium, samarium, gadolinium, terbium, dysprosium, holmium, erbium, thulium, ytterbium, and lutetium.

2. The solder alloy of claim 1 wherein said element selected from the group consisting of silver and gold is silver at a concentration of 0.1-30% by weight, and the concentration of tin is 70-99% by weight.

3. The solder alloy of claim 2 wherein said element selected from the group consisting of yttrium, lanthanum, cerium, praseodymium, scandium, samarium, gadolinium, terbium, dysprosium, holmium, erbium, thulium, ytterbium, and lutetium is lutetium.

4. The solder alloy of claim 2 wherein said element selected from the group consisting of yttrium, lanthanum, cerium, praseodymium, scandium, samarium, gadolinium, terbium, dysprosium, holmium, erbium, thulium, ytterbium, and lutetium is erbium.

5. The solder alloy of claim 2 wherein said element selected from the group consisting of yttrium, lanthanum, cerium, praseodymium, scandium, samarium, gadolinium, terbium, dysprosium, holmium, erbium, thulium, ytterbium, and lutetium is cerium.

6. The solder alloy of claim 1 wherein said element selected from the group consisting of silver and gold is gold at a concentration of 70-90% by weight, and the concentration of tin is 0.1-30% by weight.

7. The solder alloy of claim 6 wherein said element selected from the group consisting of yttrium, lanthanum, cerium, praseodymium, scandium, samarium, gadolinium, terbium, dysprosium, holmium, erbium, thulium, ytterbium, and lutetium is lutetium.

8. The solder alloy of claim 6 wherein said element selected from the group consisting of yttrium, lanthanum, cerium, praseodymium, scandium, samarium, gadolinium, terbium, dysprosium, holmium, erbium, thulium, ytterbium, and lutetium is erbium.

9. The solder alloy of claim 6 wherein said element selected from the group consisting of yttrium, lanthanum, cerium, praseodymium, scandium, samarium, gadolinium, terbium, dysprosium, holmium, erbium, thulium, ytterbium, and lutetium is cerium.

10. A packaged optoelectronic device comprising:
a. a substrate,
b. an optoelectronic device,
c. an optically transparent window,
d. the solder alloy of claim 1, wherein said solder alloy provides a seal between said substrate and said optically transparent window.

11. A method for packaging an optoelectronic device comprising:
a. providing a substrate,
b. providing an optoelectronic device,
c. providing an optically transparent window,
d. providing a sealing pre-form, wherein said sealing preform comprises the solder of claim 1,
e. bonding said optoelectronic device to said substrate,
f. contacting said sealing preform with said substrate and with said optically transparent window,
g. heating said sealing preform, thereby bonding said optically transparent window to said substrate.

12. A solder alloy comprising:
a. 30-98% by weight indium,
b. 0.5-60% by weight of an element selected from the group consisting of silver and tin,
c. 0.01-5% by weight of at least one rare earth element elected from the group consisting of yttrium, lanthanum, cerium, praseodymium, scandium, samarium, gadolinium, terbium, dysprosium, holmium, erbium, thulium, ytterbium, and lutetium,
wherein the solder alloy is substantially free of titanium, zirconium, hafnium, vanadium, niobium, and tantalum.

13. The solder alloy of claim 12 wherein the element selected from the group consisting of silver and tin is silver at a concentration of 0.5-10% by weight.

14. The solder alloy of claim 12 wherein the element selected from the group consisting of silver and tin is tin at a concentration of 20-60% by weight.

15. A packaged optoelectronic device comprising:
a. a substrate,
b. an optoelectronic device,
c. an optically transparent window,
d. the solder alloy of claim 12, wherein said solder alloy provides a seal between said substrate and said optically transparent window.

16. A method for packaging an optoelectronic device comprising:
a. providing a substrate,
b. providing an optoelectronic device,
c. providing an optically transparent window,
d. providing a sealing pre-form, wherein said sealing preform comprises the solder of claim 12,
e. bonding said optoelectronic device to said substrate,
f. contacting said sealing preform with said substrate and with said optically transparent window,
g. heating said sealing preform, thereby bonding said optically transparent window to said substrate.
